(19) United States
(12) Patent Application Publication
(10) Pub. No.: US 2025/0293168 A1
(43) Pub. Date: Sep. 18, 2025

(54) SEMICONDUCTOR DEVICE WITH INTEGRATED VOLTAGE REGULATOR

(71) Applicant: SAMSUNG ELECTRONICS CO.LTD., Suwon-si (KR)

(72) Inventors: Teng SUN, San Jose, CA (US); Jin SHI, Foster City, CA (US)

(73) Assignee: SAMSUNG ELECTRONICS CO, LTD., Suwon-si (KR)

(21) Appl. No.: 19/074,063

(22) Filed: Mar. 7, 2025

Related U.S. Application Data
(60) Provisional application No. 63/564,735, filed on Mar. 13, 2024.

(51) Int. Cl. H01L 23/538; H01L 23/14; H01L 25/18; H10D 1/20; H10D 1/60

(52) U.S. Cl. CPC H01L 23/5385; H01L 23/5389; H01L 25/18; H01L 23/145; H10D 1/20; H10D 1/60

(57) ABSTRACT

A semiconductor device and a method of manufacturing the semiconductor device are provided. The semiconductor device may include: a semiconductor chip; a hybrid interposer connected to the semiconductor chip, the hybrid interposer including a mold material and an interconnection region including a material different from the mold material, wherein the semiconductor chip is on a first surface of the hybrid interposer that faces in a first direction; and a voltage regulator module electrically connected to the semiconductor chip and configured to supply a voltage to the semiconductor chip, the voltage regulator module including an inductor that is within the hybrid interposer.

### CROSS-REFERENCE TO RELATED APPLICATION

This application claims priority from U.S. Provisional Application No. 63/564,735, filed on Mar. 13, 2024, the disclosure of which is incorporated herein by reference in its entirety.

### BACKGROUND

### 1. Field

Embodiments of the present disclosure relate to a semiconductor device and a method of manufacturing thereof, and, more particularly, a semiconductor device including an integrated voltage regulator and a method of manufacturing thereof.

### 2. Description of Background Art

New generative-artificial intelligence (AI) (e.g., ChatGPT) greatly requires graphics processing unit (GPU)/central processing unit (CPU) system-on-chip (SoC) dies with more cores to provide more computing power. Each core may be a single computing unit which is used to analyze data. A higher core count means that more data can be analyzed to give users better results. For example, ChatGPT gen1 model requires 117 million parameters, gen2 model requires 1.5 billion parameters, and gen3 model requires 175 billion parameters.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

In increasing the number of SoC dies and/or cores thereof, there may be a greater requirement for granular voltage supply to avoid generation of energy waste in the form of heat.

Embodiments of the present disclosure may address the above problems and/or other problems.

According to embodiments of the present disclosure, a semiconductor device may be provided and include: a semiconductor chip; a hybrid interposer connected to the semiconductor chip, the hybrid interposer including a mold material and an interconnection region including a material different from the mold material, wherein the semiconductor chip is on a first surface of the hybrid interposer that faces in a first direction; and a voltage regulator module electrically connected to the semiconductor chip and configured to supply a voltage to the semiconductor chip, the voltage regulator module including an inductor that is within the hybrid interposer.

According to embodiments of the present disclosure, a semiconductor device may be provided and include: a printed circuit board; a hybrid interposer connected to the printed circuit board on a first surface of the printed circuit board that faces in a first direction, the hybrid interposer including a mold material and an interconnection region including a material different from the mold material; a semiconductor chip on a first surface of the hybrid interposer that faces in the first direction; and a voltage regulator module electrically connected to the semiconductor chip and configured to supply a voltage to the semiconductor chip, the voltage regulator module including: a capacitor within the hybrid interposer; an inductor within the hybrid interposer; and a voltage regulator integrated circuit (VRIC) that is on the first surface of the hybrid interposer, and electrically connected to the capacitor and the inductor, wherein the VRIC is configured to, in combination with the capacitor and the inductor, supply the voltage.

According to embodiments of the present disclosure, a method of manufacturing a semiconductor device that includes a semiconductor chip and a voltage regulator module that is electrically connected to the semiconductor chip and configured to supply a voltage to the semiconductor chip may be provided. The method may include forming a hybrid interposer on a first surface of a carrier that faces in a first direction, the forming including: forming a first trace on the first surface of the carrier; providing an inductor of the voltage regulator module on the first surface of the carrier; providing a mold material on the first surface of the carrier such that the mold material surrounds side surfaces of the inductor; and forming a second trace on a first surface of the mold material that faces in the first direction. The method may further include providing a semiconductor chip on a first surface of the hybrid interposer that faces in the first direction.

### BRIEF DESCRIPTION OF DRAWINGS

Example embodiments of the present disclosure will be more clearly understood from the following detailed description taken in conjunction with the accompanying drawings in which:

FIG. 1 illustrates a schematic diagram of a voltage regulator module circuit;

FIG. 2 illustrates a schematic diagram of a voltage regulator module circuit;

FIG. 3 illustrates a schematic cross-sectional view of a semiconductor device according to a comparative embodiment;

FIG. 4 illustrates a schematic cross-sectional view of a semiconductor device according to a comparative embodiment;

FIG. 5 illustrates a schematic cross-sectional view of a semiconductor device according to a comparative embodiment;

FIG. 6 illustrates a schematic cross-sectional view of a semiconductor device according to an embodiment of the present disclosure;

FIG. 7 illustrates a schematic cross-sectional view of a semiconductor device according to an embodiment of the present disclosure;

FIG. 8 illustrates a flowchart for a method of manufacturing a semiconductor device according to embodiments of the present disclosure;

FIG. 9A illustrates an intermediate semiconductor device formed in an operation of the method of FIG. 8;

FIG. 9B illustrates an intermediate semiconductor device formed in an operation of the method of FIG. 8;

FIG. 9C illustrates an intermediate semiconductor device formed in an operation of the method of FIG. 8;

FIG. 9D illustrates an intermediate semiconductor device formed in an operation of the method of FIG. 8;

FIG. 9E illustrates an intermediate semiconductor device formed in an operation of the method of FIG. 8;

FIG. 9F illustrates an intermediate semiconductor device formed in an operation of the method of FIG. 8;

FIG. 9G illustrates an intermediate semiconductor device formed in an operation of the method of FIG. 8;

FIG. 9H illustrates a semiconductor device formed in an operation of the method of FIG. 8;

FIG. 10 illustrates a flowchart for a method of manufacturing a semiconductor device according to embodiments of the present disclosure;

FIG. 11A illustrates an intermediate semiconductor device formed in an operation of the method of FIG. 10;

FIG. 11B illustrates an intermediate semiconductor device formed in an operation of the method of FIG. 10;

FIG. 11C illustrates an intermediate semiconductor device formed in an operation of the method of FIG. 10;

FIG. 11D illustrates an intermediate semiconductor device formed in an operation of the method of FIG. 10;

FIG. 11E illustrates an intermediate semiconductor device formed in an operation of the method of FIG. 10;

FIG. 11F illustrates an intermediate semiconductor device formed in an operation of the method of FIG. 10;

FIG. 11G illustrates an intermediate semiconductor device formed in an operation of the method of FIG. 10;

FIG. 11H illustrates an intermediate semiconductor device formed in an operation of the method of FIG. 10; and

FIG. 11I illustrates a semiconductor device formed in an operation of the method of FIG. 10.

### DETAILED DESCRIPTION

Embodiments of the present disclosure described herein are example embodiments, and thus, the present disclosure is not limited thereto, and may be realized in various other forms. Each of the embodiments provided in the following description is not excluded from being associated with one or more features of another embodiment also provided herein or not provided herein but consistent with the present disclosure. For example, even if matters described in a specific example embodiment are not described in a different example embodiment, the matters may be understood as being related to or combined with the different example embodiment, unless otherwise mentioned in descriptions thereof. In addition, it should be understood that all descriptions of principles, aspects, examples, and embodiments of the present disclosure are intended to encompass structural and functional equivalents thereof. In addition, these equivalents should be understood as including not only currently well-known equivalents but also equivalents to be developed in the future, that is, all devices that perform the same functions regardless of the structures thereof.

It will be understood that when an element, component, layer, pattern, structure, region, or so on (hereinafter collectively “element”) of a semiconductor device is referred to as being “on,” “connected to,” or “coupled to” another element the semiconductor device, it can be directly on, connected to, or coupled to the other element or an intervening element(s) may be present. In contrast, when an element of a semiconductor device is referred to as being “directly on,” “directly connected to,” or “directly coupled to” another element of the semiconductor device, there are no intervening elements present. Like numerals refer to like elements throughout the present disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “first” element or a “second” element, respectively, as long as their structural relationship is clearly understood in the context of the descriptions. Similarly, the terms a “lower” element and an “upper” element may be respectively referred to as a “first” element and a “second” element to distinguish the two elements.

It will be understood that, although the terms “first,” “second,” “third,” “fourth,” “fifth,” “sixth,” etc. may be used herein to describe various elements, these elements should not be limited by these terms. These terms are only used to distinguish one element from another element. Thus, a first element discussed below could be termed a second element without departing from the scope of the present disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” or “equal” is used to compare a dimension of two or more elements, the term may cover a “substantially same” or “substantially equal” dimension.

It will be also understood that, when a method of manufacturing an apparatus or structure is described as including a plurality of steps or operations, a certain step or operation described as being performed later than another step or operation may be performed prior to or at the same time as the other step or operation unless the other step or operation is described as necessarily being performed prior to the step or operation. Further, the method may include additional steps or operations not mentioned in the description.

Many example embodiments are described herein with reference to cross-sectional views that are schematic illustrations of the embodiments (and intermediate structures). As such, variations from the shapes of the illustrations as a result of, for example, manufacturing techniques and/or tolerances are to be expected. Thus, the embodiments should not be construed as limited to the particular shapes of regions illustrated herein, and are to include deviations in shapes that result from, for example, manufacturing. Various regions illustrated in the figures are schematic in nature and their shapes may not be intended to illustrate the actual shape of a region of a device and are not intended to limit the scope of the present disclosure. Further, in the drawings, the sizes and relative sizes of layers and regions may be exaggerated for clarity.

For the sake of brevity, conventional elements, structures, or layers included in a semiconductor package including a connection pad, an adhesive layer, an isolation layer, a barrier metal pattern, a seed layer, etc. may or may not be described in detail herein. For example, descriptions of certain connection pads of a semiconductor chip connected to solder balls or bumps in a semiconductor package may be omitted herein when these structural elements are not related to certain features of the embodiments. Also, descriptions of materials forming well-known structural elements may be omitted herein when those materials are not relevant to certain features of the embodiments. Herein, the term “connection” between two structures or elements may refer to an electrical connection therebetween. For example, a connection between semiconductor chips, semiconductor packages, and/or semiconductor devices may refer to an electrical connection of a corresponding two or more elements to each other. The terms “coupled” and “connected” may have the same meaning and may be used interchangeably herein. Further, the term “isolation” between two structures or elements pertains to electrical insulation or separation therebetween. For example, isolation of wiring patterns from each other may mean that the wiring patterns are not electrically connected to each other.

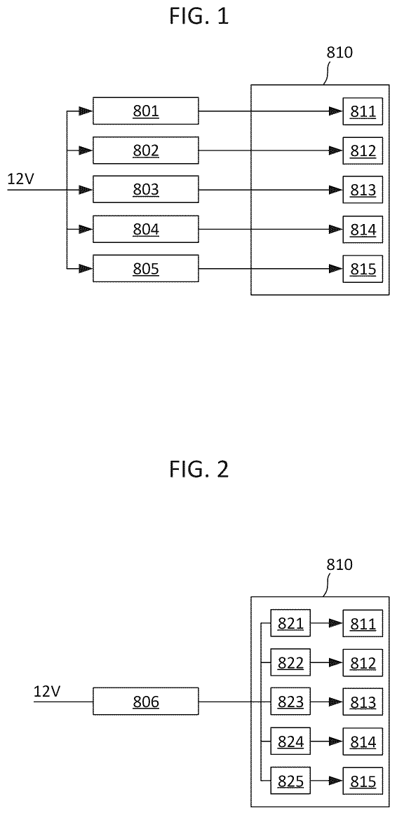

Hereinafter, various example embodiments of the present disclosure are described with reference to FIGS. 1-11I.

One of the challenges of comparative embodiments that prevent CPU/GPU core scaling is granular voltage supply. To maintain function, a stable voltage may be needed for the cores. For example, with reference to FIG. 1, a plurality of voltage regulator modules (VRMs) may be on a printed circuit board (PCB) and may each be configured to receive voltage (e.g., 12V) from a main power source, convert the voltage to a lower voltage, and supply the converted voltage to a respective one of the cores of at least one semiconductor chip 810 (e.g., an SoC) on the PCB. Each of the cores may require a different voltage depending on the function of the core. For example, a first VRM 801 may convert the voltage to be in a range of 0.7 to 1.1 V, with a current of about 250 A, and supply the converted voltage to a first core 811 that may require 1.1 V; a second VRM 802 may convert the voltage from the main power source to be 1.1 V, with a current of about 50 A, and supply the converted voltage to a second core 812 that may require 1.1 V; a third VRM 803 may convert the voltage from the main power source to be in a range of 0.6 to 0.8 V, with a current of about 30 A, and supply the converted voltage to a third core 813 that may require 0.8 V; a fourth VRM 804 may convert the voltage from the main power source to be in a range of 0.8 to 1.0 V, with a current of about 25 A, and supply the converted voltage to a fourth core 814 that may require 1.0 V; and a fifth VRM 805 may convert the voltage from the main power source to be 1.5 V, with a current of about 5 A, and supply the converted voltage to a fifth core 815 that may require 1.5 V. Each of the VRMs (e.g., the first through fifth VRMs 801-805) may include, for example, a circuit configured to perform the functions of the VRM, and the circuit may include a resistor, capacitor, and/or an inductor.

Ideally, as shown in FIG. 1, each core (e.g., the first through fifth cores 811-815) should be connected to a respective VRM (e.g., the first through fifth VRMs 801-805) that supplies a regulated voltage to the core. For example, for an artificial intelligence (AI) SoC with 108 cores, 108 VRMs are ideally on a PCB and respectively connected to the 108 cores on the PCB.

However, due to size limitations of a PCB in a comparative embodiment, only about 20 VRMs can be placed on the PCB, resulting in five cores sharing one VRM or one voltage supply. For example, with reference to FIG. 2, the first through fifth cores 811-815 may share a single VRM 806 on the PCB. For example, the single VRM 806 may convert 12 V to 1.7 V, the converted voltage of the single VRM 806 may be supplied to first through fifth integrated voltage regulators 821-825 of the chip 810, and the first through fifth integrated voltage regulators 821-825 may convert the 1.7 V to respective voltages (e.g., within a range of 0.6 V to 1 V) and supply the respective voltages to the first through fifth cores 811-815, respectively. However, because cores (e.g., the first through fifth cores 811-815) share voltage from the single VRM 806, some of the cores may receive excess voltage supply, which turns into energy waste in the form of heat. The excess heat can prevent scaling of core counts for future AI SoCs.

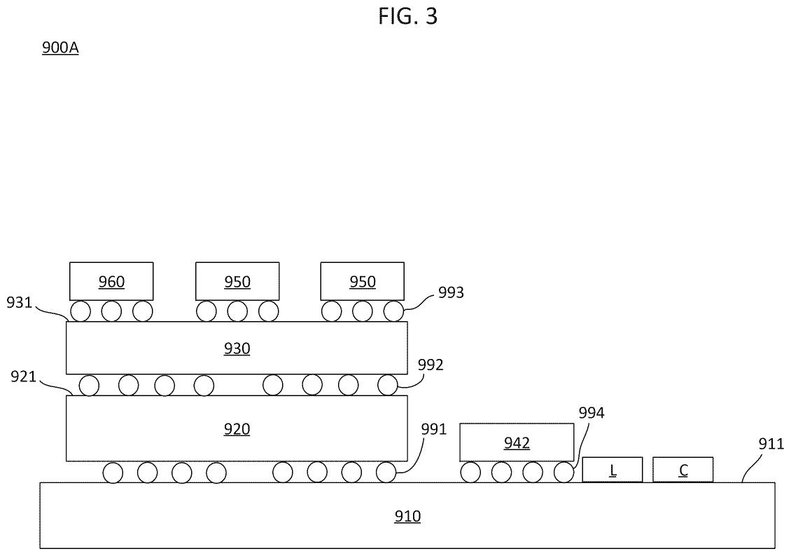

According to comparative embodiments, in an attempt to increase the number of VRMs that may be placed on the PCB, the VRMs are placed further away from the cores and connected to the cores by a long power delivery network (PDN) that may include, for example, long Cu traces. For example, with reference to FIG. 3, a semiconductor device 900A may be provided that includes a PCB 910, a substrate 920, an interposer 930, SoCs 950, a high bandwidth memory (HBM) 960, and VRMs.

Each of the VRMs may be mounted on a top surface 911 of the PCB 910, and may each include, for example, a voltage regulator integrated circuit (VRIC) 942, an inductor L, and a capacitor C. Each VRM (e.g., the VRIC 942 thereof) may be electrically connected to the PCB 910 by at least one bump 994 between the PCB 910 and the VRM (e.g., the VRIC 942 thereof).

The substrate 920 may be mounted on the top surface 911 of the PCB 910 and may be electrically connected to the PCB 910 by at least one bump 991 between the PCB 910 and the substrate 920. The PCB 910 and the substrate 920 may be formed of an organic material (e.g., polymer).

The interposer 930 may be mounted on a top surface 921 of the substrate 920 and may be electrically connected to the substrate 920 by at least one bump 992 between the substrate 920 and the interposer 930. The interposer 930 may be, for example, a semiconductor material interposer (e.g., a silicon interposer) that is formed of a semiconductor material (e.g., Si), and the semiconductor device 900A may include a 2.5D package architecture. Alternatively, the interposer 930 may be a mold-semiconductor material hybrid interposer (e.g., a mold-Si hybrid interposer), and the semiconductor device 900A may include a 2.3D package architecture. The mold-semiconductor material hybrid interposer may be primarily formed of a mold material, and may further include a semiconductor material (e.g., Si) in areas where interconnection elements are provided in the mold-semiconductor material hybrid interposer to electrically connect the SoCs 950 and electrically connect one or more of the SoCs 950 to the HBM 960.

The SoCs 950 and the HBM 960 may be mounted on a top surface 931 of the interposer 930 and may be electrically connected to the interposer 930 by at least one bump 993 between the SoCs 950 (or the HBM 960) and the interposer 930. The SoCs 950 and the HBM 960 may be semiconductor chips and may include a semiconductor material (e.g., silicon).

According to the configuration shown in FIG. 3, the VRMs may be electrically connected to the SoCs 950 by a PDN that includes one or more of the bumps 944, the PCB 910, one or more of the bumps 991, the substrate 920, one or more of the bumps 992, the interposer 930, one or more of the bumps 993, and at least one copper trace associated with (e.g., on) the PCB 910, the substrate 920, and/or the interposer 930. Accordingly, the PDN (e.g., the Cu traces) is long and there may be a large amount of energy waste and lower efficiency.

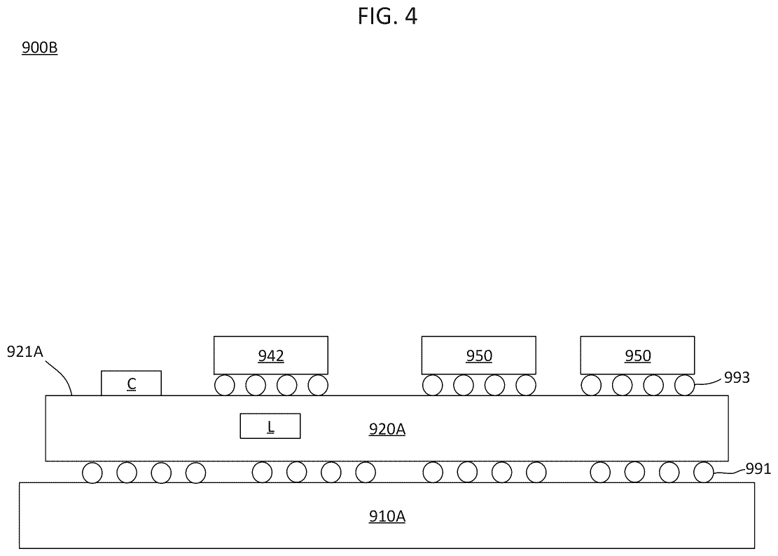

According to another comparative embodiment, with reference to FIG. 4, a semiconductor device 900B may be provided that includes a PCB 910A, a substrate 920A, the SoCs 950, and the VRMs. The PCB 910A may be substantially the same as the PCB 910 described with reference to FIG. 3. The substrate 920A may be substantially the same as the substrate 920 described with reference to FIG. 3. In the semiconductor device 900B, an interposer (e.g., the interposer 930 of FIG. 3) may be omitted, the VRIC 942 and the capacitor C of the VRMs may be mounted on a top surface 921A of the substrate 920A, and the inductor L of the VRMs may be within the substrate 920A.

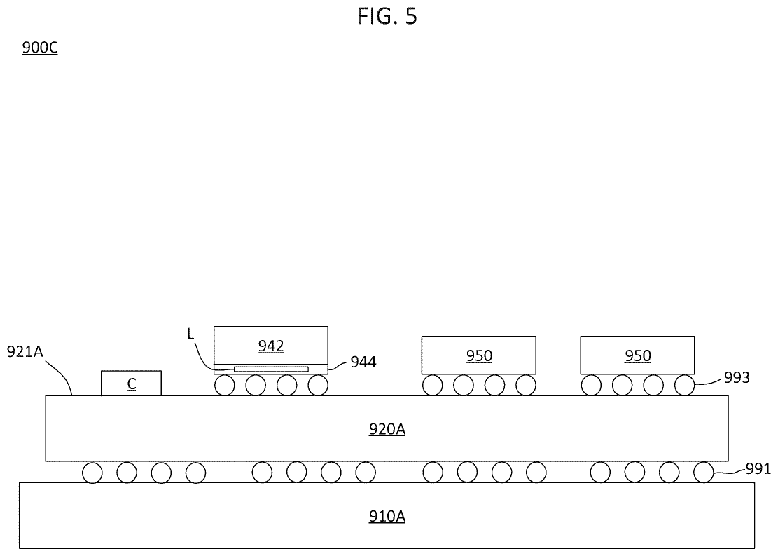

According to another comparative embodiment, with reference to FIG. 5, a semiconductor device 900C may be provided. In the semiconductor device 900C, the inductor L may be included in a layer 944 at a backside of a chip that constitutes the VRIC 942. That is, the entirety of the VRMs may be mounted on the top surface 921A of the substrate 920A.

While the semiconductor device 900B and the semiconductor device 900C of FIGS. 4-5 may have a shorter PDN associated with the VRMs in comparison to the semiconductor device 900A of FIG. 3, the semiconductor device 900B and the semiconductor device 900C lack a high interconnection density interposer, which is a key enabler for the design of chiplets. With the trend to have a higher number of dies for AI/data-center products (e.g., chiplets), there is a need for a solution that incorporates both VRMs and a high interconnection density interposer to facilitate a large number of chiplets while reducing energy waste and avoiding performance degradation.

To enable granular voltage supply, some or all of the components (e.g., inductor and capacitors) of the VRMs may need to be minimized in size so that a semiconductor device can include more VRMs to supply cores with their respective voltage supplies, without increasing the size of the PCB. The size of capacitors can be minimized easily without reducing performance. However, for inductors, there is a trade-off between size and performance. To avoid performance degradation, magnetic material may be included in the inductors. For example, when a high-permeability magnetic material such as Ni, Fe, or Co is used as core of the inductor, the size of the inductor can be minimized without performance degradation.

To enable shorter power deliver length, some or all of the components (e.g., inductors and capacitors) of the VRM may need to be placed directly under chip dies (e.g., SoC dies). However, a lack of integration processes, particularly with respect to interposers, has created a large difficulty in realizing such a configuration. For example, it is difficult to integrate components of the VRM into an Si interposer, which is used in the 2.5D package architecture.

Embodiments of the present disclosure provide semiconductor devices and methods of manufacturing the semiconductor devices that provide solutions to the above problems and/or other problems.

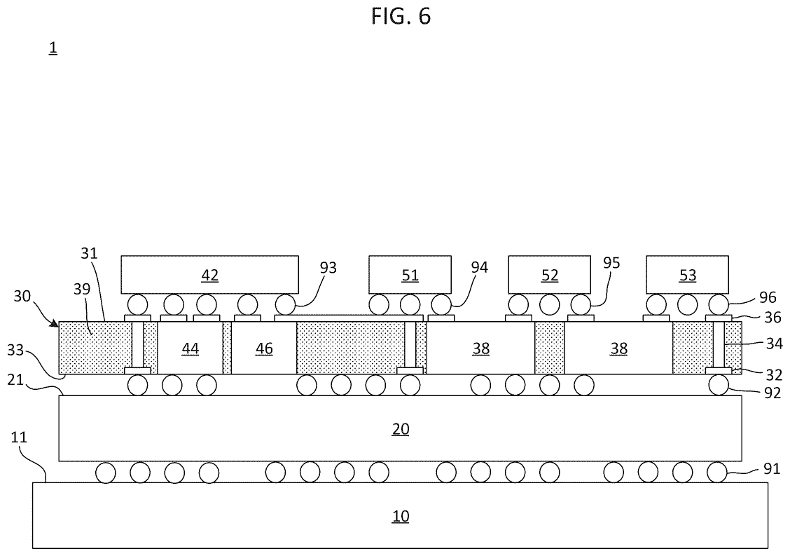

For example, with reference to FIG. 6, a semiconductor device 1 (e.g., a semiconductor package) according to an embodiment of the present disclosure may include a PCB 10, a substrate 20, an interposer 30, at least one semiconductor chip (e.g., a first semiconductor chip 51 and a second semiconductor chip 52), a memory 53 (e.g., a third semiconductor chip), and VRMs. According to embodiments, one or more of the at least one semiconductor chip (e.g., the first semiconductor chip 51 and the second semiconductor chip 52) may be an SoC, and the memory 53 (e.g., the third semiconductor chip) may be an HBM, but embodiments of the present disclosure are not limited thereto.

The substrate 20 may be mounted on a top surface 11 of the PCB 10 and may be electrically connected to the PCB 10 by at least one bump 91 between the PCB 10 and the substrate 20. The PCB 10 and the substrate 20 may be formed of an organic material (e.g., polymer).

The interposer 30 may be mounted on a top surface 21 of the substrate 20 and may be electrically connected to the substrate 20 by at least one bump 92 between the substrate 20 and the interposer 30. The interposer 930 may be, for example, a mold-semiconductor material hybrid interposer (e.g., a mold-Si hybrid interposer), and the semiconductor device 1 may include a 2.3D package architecture. The mold-semiconductor material hybrid interposer may be primarily formed of a mold material 39, and may further include a semiconductor material (e.g., Si) in areas where interconnection elements are provided in the mold-semiconductor material hybrid interposer to electrically connect semiconductor chips (e.g., the first semiconductor chip 51 and the second semiconductor chip 52) and electrically connect one or more of the semiconductor chips e.g., the first semiconductor chip 51 and the second semiconductor chip 52) to the memory 53. For example, the areas in which the semiconductor material (e.g., Si) is included may be interconnection regions 38 that include the semiconductor material (e.g., Si). The interposer 30 may further include a first trace 32 (e.g., a copper trace), one or more posts 34 (e.g., copper posts), and a second trace 36 (e.g., a copper trace). The first trace 32 may be at a bottom side of the interposer 30, the second trace 36 may be at a top side of the interposer 30, and the one or more posts 34 may penetrate the mold material 39 such as to electrically connect together the first trace 32 and the second trace 36. According to an embodiment, the first trace 32 may be recessed in a bottom surface 33 of the mold material 39 such that a bottom surface of the first trace 32 and the bottom surface 33 of the mold material 39 are coplanar. According to an embodiment, a bottom surface of the second trace 36 is formed on the top surface 31 of the mold material 39 such that the second trace 36 protrudes upwards from the mold material 39. However, embodiments of the present disclosure are not limited thereto. For example, the first trace 32 may protrude from the bottom surface 33 of the mold material 39 and/or the second trace 36 may be recessed in the top surface 31 of the mold material 39 such that the top surface of the first trace 32 and the top surface 31 of the mold material 39 are coplanar. According to embodiments, each of the first trace 32 and the second trace 36 may extend in one or more horizontal directions (e.g., x and/or y directions).

The semiconductor chips (e.g., the first semiconductor chip 51 and the second semiconductor chip 52) and the memory 53 (e.g., a third semiconductor chip) may be mounted on the top surface 31 of the interposer 30. The first semiconductor chip 51 may be electrically connected to the second trace 36 by at least one bump 94 between the first semiconductor chip 51 and the second trace 36, the second semiconductor chip 52 may be electrically connected to the second trace 36 by at least one bump 95 between the second semiconductor chip 52 and the second trace 36, and the memory 53 may be electrically connected to the second trace 36 by at least one bump 96 between the memory 53 and the second trace 36. The semiconductor chips (e.g., the first semiconductor chip 51 and the second semiconductor chip 52) and the memory 53 may include a semiconductor material (e.g., silicon). According to embodiments, any number of the semiconductor chips (e.g., the first semiconductor chip 51 and the second semiconductor chip 52) may receive power from a respective one of the VRMs and/or two or more of the semiconductor chips may receive power supplied from a same VRM. According to embodiments, the semiconductor chips (e.g., the first semiconductor chip 51 and the second semiconductor chip 52) may include one or more cores, and any number of the cores may receive power from a respective one of the VRMs and/or two or more of the cores (of a same or different semiconductor chip) may receive power supplied from a same VRM. According to embodiments, the semiconductor chips (e.g., the first semiconductor chip 51 and the second semiconductor chip 52) may be chips configured to perform processing. For example, the chips may be or may be a part of a GPU, a CPU, a data processing unit (DPU), etc., but embodiments of the present disclosure are not limited thereto.

In FIG. 6, a single VRM is shown for purposes of clarity, and a person of ordinary skill in the art would have understood that a plurality of the VRMs may be provided in the embodiment illustrated in FIG. 6 in, for example, a same or similar manner as the single VRM.

The VRMs may each include, for example, a voltage regulator integrated circuit (VRIC) 42, an inductor 44, and a capacitor 46. For example, the VRIC 42 may be a semiconductor chip, may be mounted on the top surface 31 of the interposer 30, and may be electrically connected to the second trace 36 by at least one bump 93 between the VRIC 42 and the second trace 36. According to embodiments, the VRC 42, in combination with the inductor 44 and/or the capacitor 46, may be configured to regulate and supply a voltage to one or more of the semiconductor chips (e.g., the first semiconductor chip 51 and the second semiconductor chip 52). One or both of the inductor 44 and the capacitor 46 may be integrated within the interposer 30. For example, sides of the inductor 44 and the capacitor 46 may be surrounded by and in contact with the mold material 39, top surfaces of the inductor 44 and the capacitor 46 may be coplanar with the top surface 31 of the mold material 39, and bottom surfaces of the inductor 44 and the capacitor 46 may be coplanar with the bottom surface 33 of the mold material 39. According to embodiments, one or both of the inductor 44 and the capacitor 46, within the interposer 30, may be overlapped by (e.g., directly below) the VRIC 42 or may be adjacent to the VRIC 42 in a horizontal direction, when viewed in a plan view (e.g., from a vertical direction). According to embodiments, one or both of the inductor 44 and the capacitor 46, within the interposer 30, may be overlapped by (e.g., directly below) one or more of the semiconductor chips (e.g., the first semiconductor chip 51 and the second semiconductor chip 52) and/or the memory 53, or may be adjacent to one or more of the semiconductor chips (e.g., the first semiconductor chip 51 and the second semiconductor chip 52) in a horizontal direction when viewed in a plan view.

According to embodiments, the capacitor 46 may be closer than the inductor 44 to at least one semiconductor chip (e.g., the first semiconductor chip 51 and/or the second semiconductor chip 52) connected to the VRM. For example, with reference to FIG. 6, the capacitor 46 may be on a right side of the inductor 44. However, embodiments of the present disclosure are not limited thereto. For example, the inductor 44 may be closer than the capacitor 46 to at least one semiconductor chip (e.g., the first semiconductor chip 51 and/or the second semiconductor chip 52) connected to the VRM. For example, with reference to FIG. 6, the inductor 44 may be on a right side of the capacitor 46. For example, positions of the inductor 44 and the capacitor 46 shown in FIG. 6 may be switched with each other.

According to embodiments, two or more from among the VRIC 42, the inductor 44, the capacitor 46, the first semiconductor chip 51, the second semiconductor chip 52, and the memory 53 may be electrically connected together by one or more from among the first trace 32, the posts 34, the second trace 36, and the interconnection regions 38. For example, the components (e.g., the VRIC 42, the inductor 44, and the capacitor 46) of the VRMs may be electrically connected to the first semiconductor chip 51 and the second semiconductor chip 52 by the second trace 36, or by two or more from among the first trace 32, the posts 34, the second trace 36, and the interconnection regions 38.

According to embodiments, one or more from among the VRIC 42, the inductor 44, the capacitor 46, the first semiconductor chip 51, the second semiconductor chip 52, and the memory 53 may be electrically connected to the substrate 20 by at least one of the bumps 92 and one or more from among the first trace 32, the posts 34, the second trace 36, and the interconnection regions 38. According to embodiments, the one or more from among the VRIC 42, the inductor 44, the capacitor 46, the first semiconductor chip 51, the second semiconductor chip 52, and the memory 53 may be further electrically connected to the PCB 10 by at least one bump 91. For example, through the electrical connection to the substrate 20 and/or the PCB 10, the VRM may receive power from a power supply (e.g., a main power supply), and the VRM may convert a voltage of the power received from the power supply.

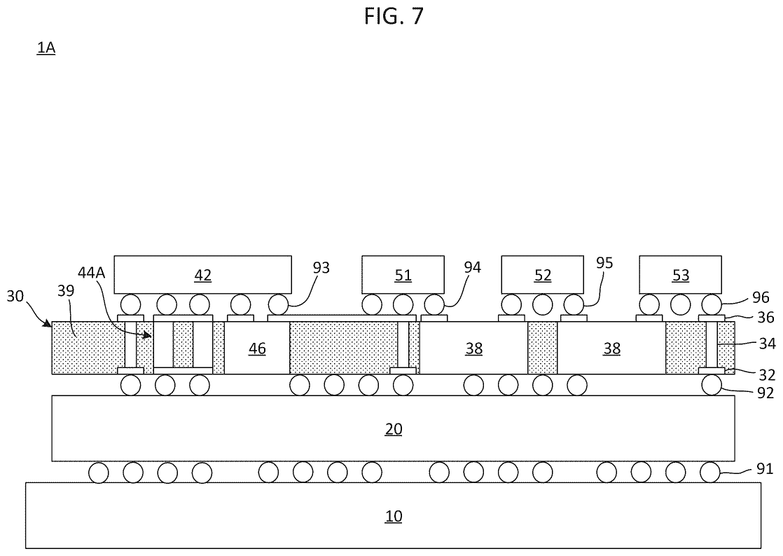

According to embodiments, the inductor 44 may include a core formed of high-permeability magnetic material such as, for example, one or more from among Ni, Fe, Co, etc. For example, the inductor 44 may be a semiconductor material (e.g., Si) magnetic core inductor having a core that is formed by a sputtering process. Alternatively, with reference to FIG. 7, the inductor may be an electroplated magnetic core inductor 44A having a core formed by an electroplating process. According to embodiments, the inductor 44 and the electroplated magnetic core inductor 44A may include one or more terminals (e.g., copper terminals) electrically connected to the first trace 32 and/or the second trace 34.

According to embodiments, the capacitor 46 may be an integrated stack capacitor (ISC). According to embodiments, the capacitor 46 may include one or more terminals (e.g., copper terminals) electrically connected to the first trace 32 and/or the second trace 34.

According to embodiments, one from among the inductor 44 (or the electroplated magnetic core inductor 44A) and the capacitor 46 may be integrated within the interposer 30, and the other from among the inductor 44 (or the electroplated magnetic core inductor 44A) and the capacitor 46 may be mounted on the top surface 31 of the interposer 30 or mounted on the top surface 11 of the PCB 10 (refer to FIG. 3-5).

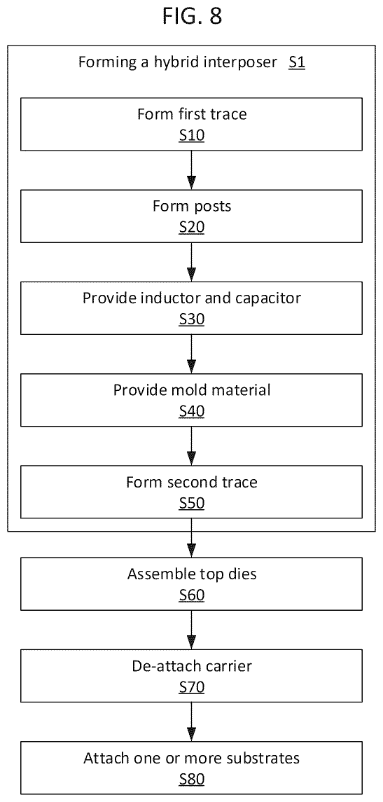

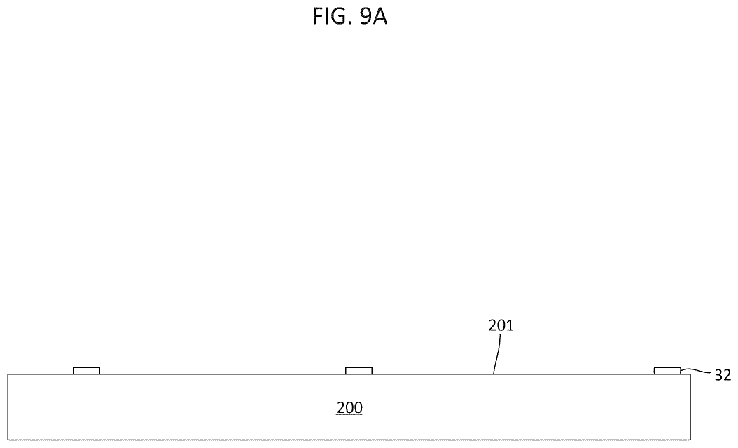

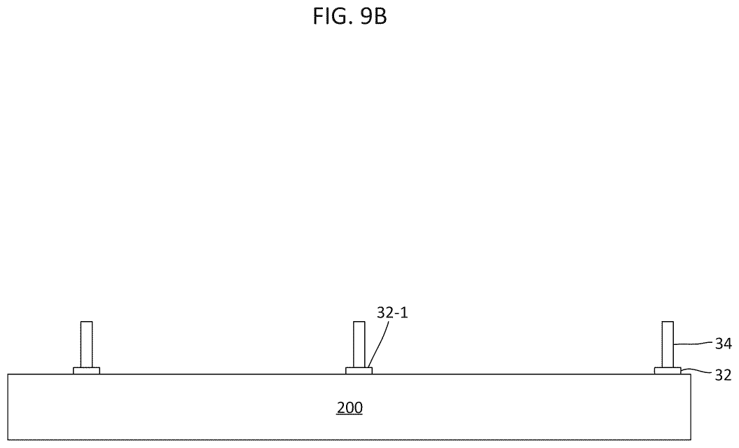

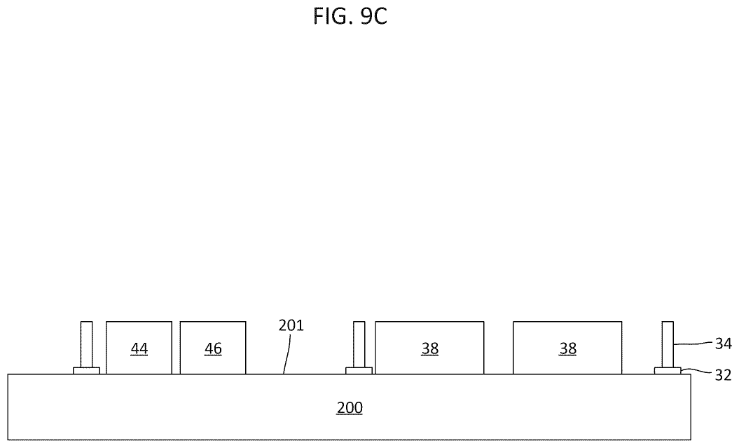

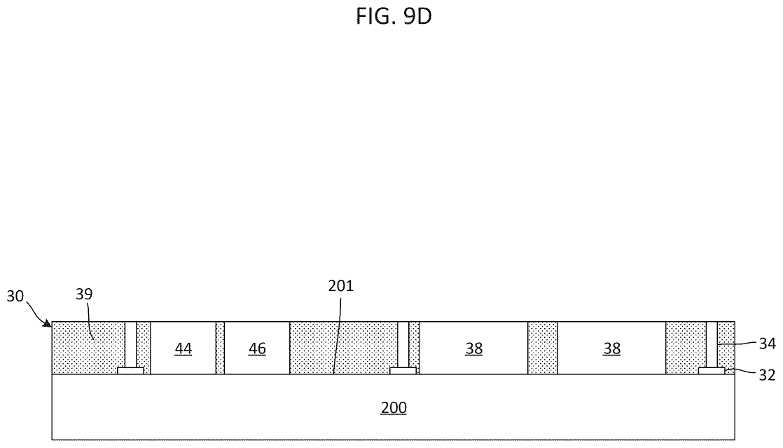

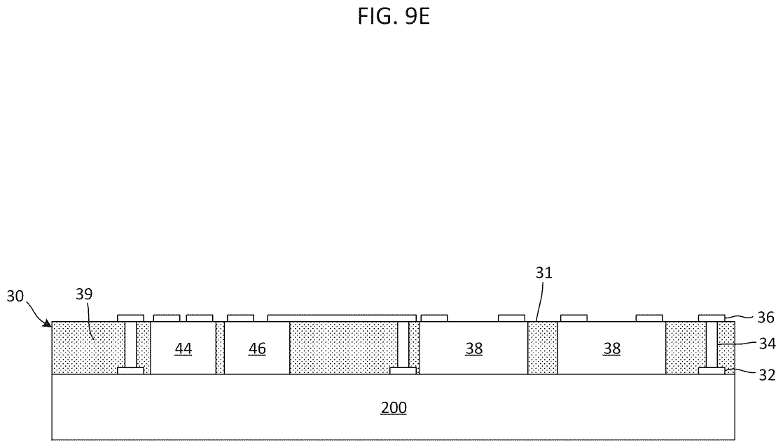

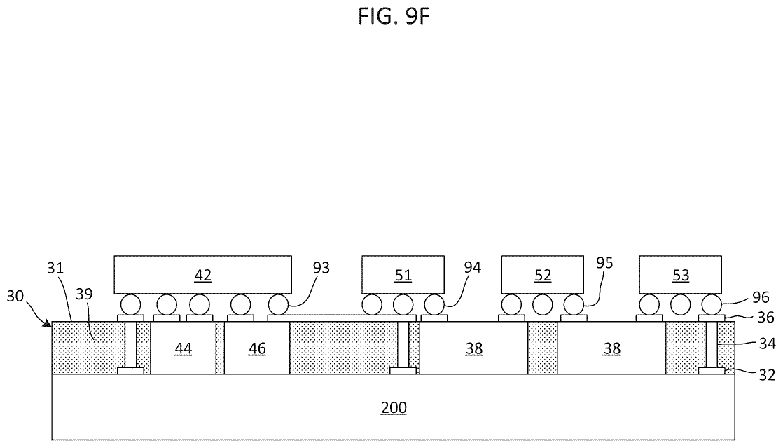

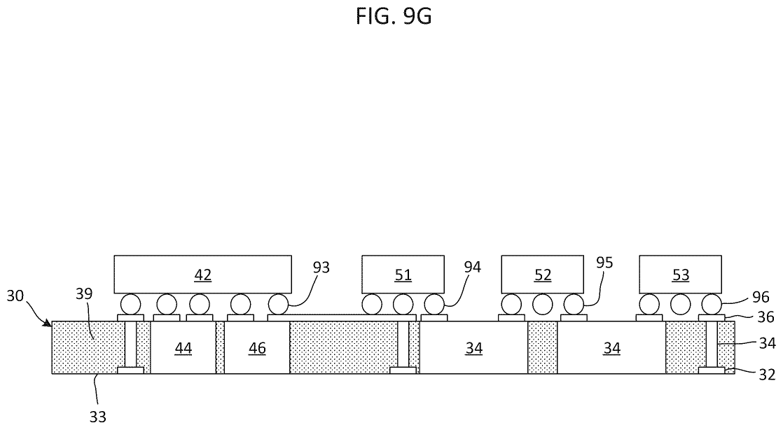

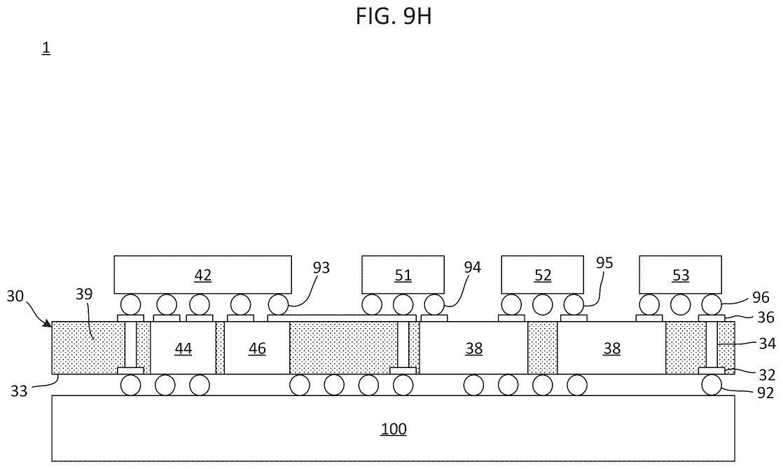

With reference to FIGS. 8 and 9A-H, a manufacturing process of the semiconductor device 1 of FIG. 6 is described below.

FIG. 8 illustrates a flowchart for a method of manufacturing a semiconductor device according to embodiments of the present disclosure. FIGS. 9A-G illustrate intermediate semiconductor devices formed in processes of the method of FIG. 8. FIG. 9H illustrates a semiconductor device formed in an operation of the method of FIG. 8.

According to embodiments, the manufacturing process may include forming a hybrid interposer (e.g., interposer 30) (operation S1), which may include forming the first trace 32 (operation S10), forming the posts 34 (operation S20), providing the inductor 44 and/or the capacitor 46 (operation S30), providing the mold material 39 (operation S40), and forming the second trace 36 (operation S50). The method may further including assembling top dies (operation S60), de-attaching a carrier (operation S70), and attaching one or more substrates 100 (operation S80).

With reference to FIG. 9A, operation S10 may include forming the first trace 32 (e.g., a copper trace) on a surface 201 (e.g., a top surface) a carrier 200. The carrier 200 may be a substrate configured to support components thereon during a manufacturing process.

With reference to FIG. 9B, operation S20 may include forming one or more posts 34 (e.g., copper posts) on a surface (e.g., top surface 32-1) of the first trace 32.

With reference to FIG. 9C, operation S30 may include providing the inductor 44 and/or the capacitor 46 on the surface 201 (e.g., top surface) of the carrier 200. For example, the inductor 44 and/or the capacitor 46 may be placed between two of the posts 34. For example, the core of the inductor 44 may be formed via a sputtering process performed on the surface 201 (e.g., top surface) of the carrier 200. According to embodiments, operation S30 may further include forming one or more of the interconnection regions 38 on the surface 201 (e.g., top surface) of the carrier 200. For example, the one or more of the interconnection regions 38 may be formed between two of the posts 34.

With reference to FIG. 9D, operation S40 may include providing the mold material 39 on the surface 201 (e.g., top surface) of the carrier 200 to fill gaps between components on the carrier 200. For example, the mold material 39 may be applied such as to surround and contact side and top surfaces of the first trace 32 and side surfaces of the posts 34, the inductor 44, the capacitor 46, and the interconnection regions 38. According to embodiments, the providing the mold material 39 may include covering a top surface of at least one from among the posts 34, the inductor 44, the capacitor 46, and the interconnection regions 38 with the mold material 39, and planarizing (e.g., grinding) the corresponding structure such that top surfaces of the posts 34, the inductor 44, the capacitor 46, and the interconnection regions 38 become exposed and coplanar with the top surface of the mold material 39.

With reference to FIG. 9E, operation S50 may include forming the second trace 36 on a surface (e.g., the top surface 31) of the mold material 39.

With reference to FIG. 9F, operation S60 may include assembling the top dies. For example, the top dies may include at least one VRIC 42, the first semiconductor chip 51, the second semiconductor chip 52, and the memory 53. For example, the assembling the top dies may include providing the at least one VRIC 42, the first semiconductor chip 51, the second semiconductor chip 52, and the memory 53 on a surface (e.g., top surface 31) of the interposer 30. For example, operation S60 may include providing bumps (e.g., the bumps 93, the bumps 94, the bumps 95, and the bumps 96) on the second trace 36, and then attaching the at least one VRIC 42, the first semiconductor chip 51, the second semiconductor chip 52, and the memory 53 onto the bumps. Alternatively, operation S60 may include attaching the at least one VRIC 42, the first semiconductor chip 51, the second semiconductor chip 52, and the memory 53, with the bumps attached thereon, onto the surface (e.g., top surface 31) of the interposer 30. According to embodiment, in a case where one from among the inductor 44 and the capacitor 46 is to be mounted (e.g., surface mounted) on the surface (e.g., top surface 31) of the interposer 30, operation S60 may further include assembling the one from among the inductor 44 and the capacitor 46 onto the surface (e.g., top surface 31) of the interposer 30. Surface mounting may include, for example, adhering (e.g., with an adhesive layer) the component to the surface.

With reference to FIG. 9G, operation S70 may include de-attaching the carrier 200 (refer to FIG. 9F) from a surface (e.g., bottom surface 33) of the interposer 30.

With reference to FIG. 9H, operation S80 may include attaching one or more substrates 100 onto the surface (e.g., bottom surface 33) of the interposer 30 from which the carrier 200 was removed. For example, the one or more substrates 100 may include the PCB 10 and/or the substrate 20. For example, operation S80 may include providing bumps 92 onto the surface (e.g., bottom surface 33) of the interposer 30 and attaching the one or more substrates 100 to the bumps 92. Alternatively, operation S80 may include attaching the one or more substrates 100, with the bumps attached thereon, onto the surface (e.g., bottom surface 33) of the interposer 30.

According to the above, the semiconductor device 1 may be manufactured.

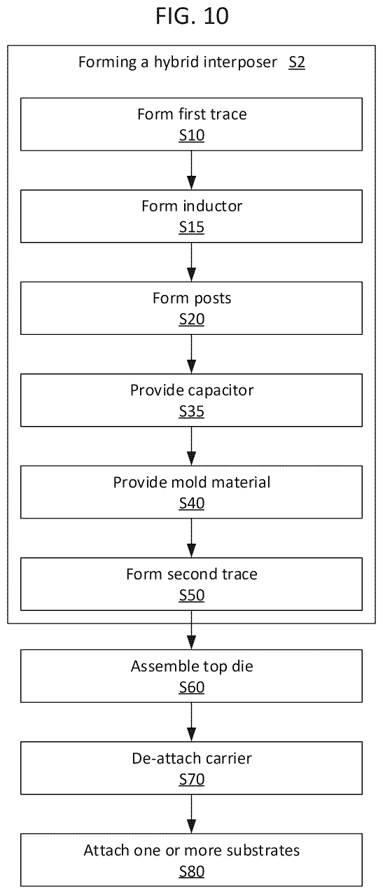

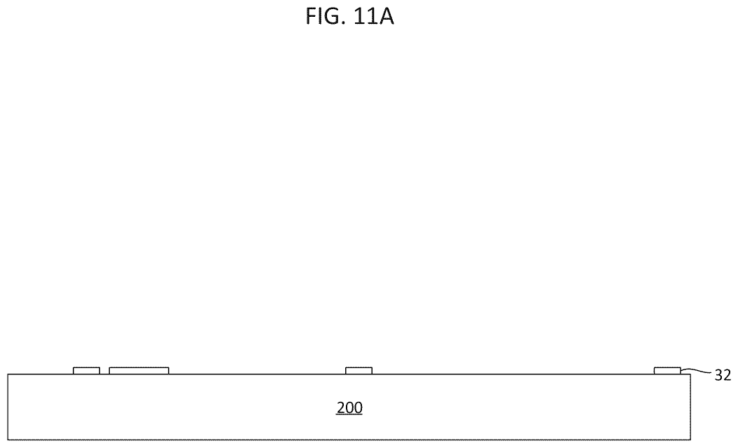

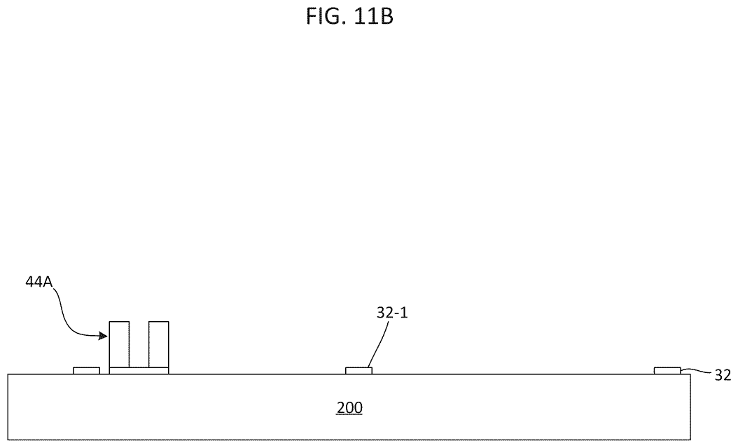

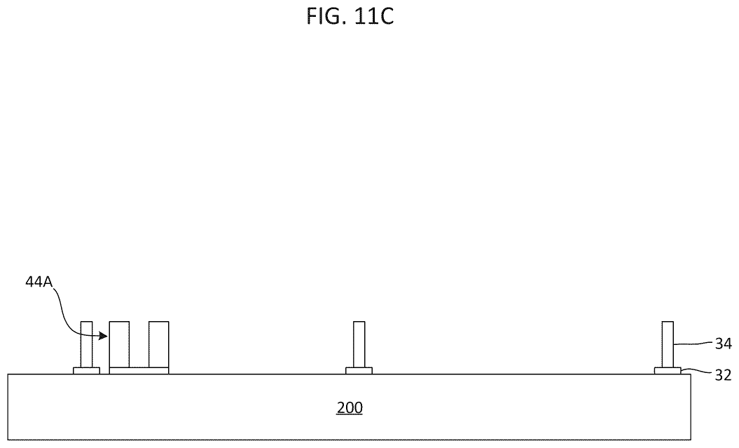

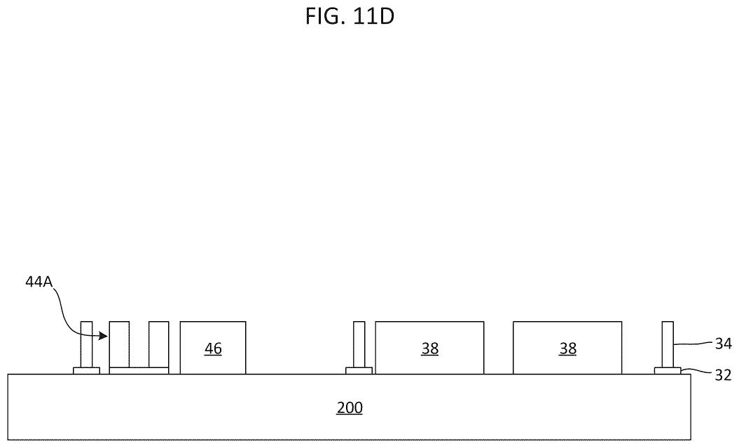

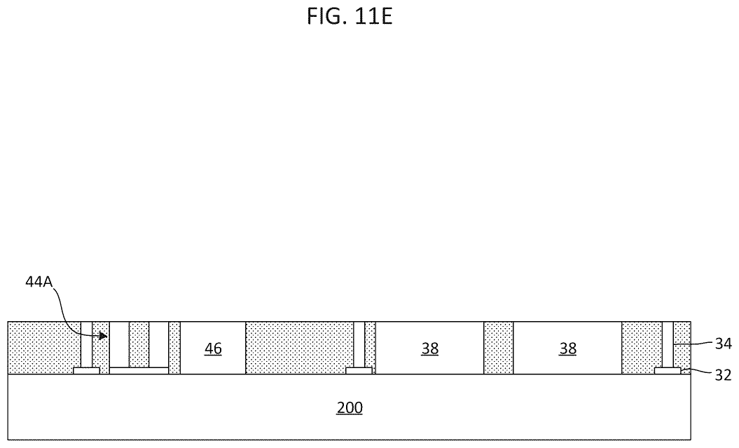

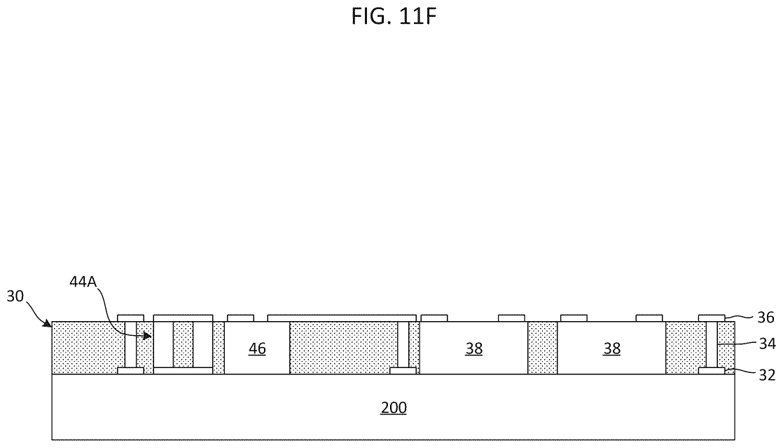

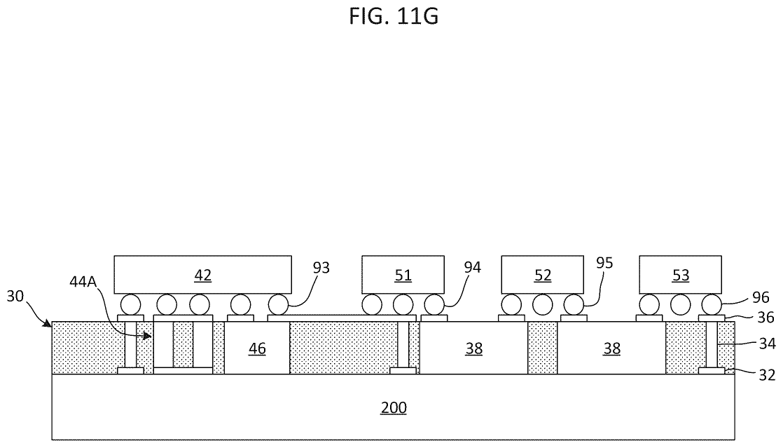

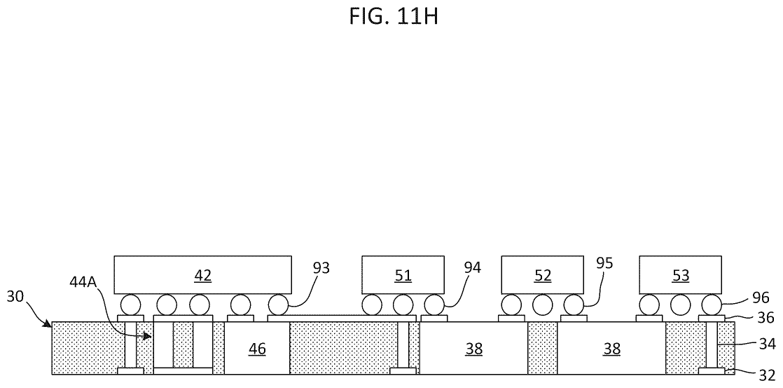

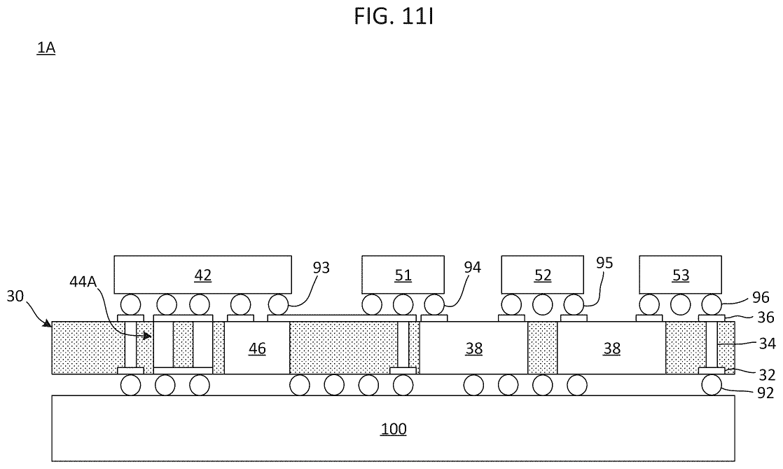

With reference to FIGS. 10 and 11A-H, a manufacturing process of the semiconductor device 1A of FIG. 7 is described below. The manufacturing process of the semiconductor device 1A of FIG. 7 may be similar to the manufacturing process of the semiconductor device 1 of FIG. 6, except operations related to forming the electroplated magnetic core inductor 44A are provided. Accordingly, differences from the manufacturing process of the semiconductor device 1 of FIG. 6 is mainly described below, and repeated descriptions may be omitted.

FIG. 10 illustrates a flowchart for a method of manufacturing a semiconductor device according to embodiments of the present disclosure. FIGS. 11A-G illustrate intermediate semiconductor devices formed in processes of the method of FIG. 10. FIG. 11H illustrates a semiconductor device formed in an operation of the method of FIG. 8.

According to embodiments, the manufacturing process may include forming a hybrid interposer (e.g., interposer 30) (operation S2), which may include forming the first trace 32 (operation S10), forming the electroplated magnetic core inductor 44A (operation S15), forming the posts 34 (operation S20), providing the capacitor 46 (operation S35), providing the mold material 39 (operation S40), and forming the second trace 36 (operation S50). The manufacturing process may further include assembling top dies (operation S60), de-attaching a carrier 200 (operation S70), and attaching one or more substrates 100 (operation S80).

With reference to FIG. 11B, operation S15 may include forming the electroplated magnetic core inductor 44A on a surface (e.g., top surface 32-1) of the first trace 32. For example, the core of the electroplated magnetic core inductor 44A may be electroplated on the first trace 32 to form the electroplated magnetic core inductor 44A. For example, as shown in FIG. 11B, the core may be formed by forming two posts, extending upwards from the top surface 32-1 of the first trace 32, via electro. The two posts, forming the core, may be a magnetic material and may be a metal. According to embodiments, operation S15 may be performed prior to forming the posts 34 (operation S20), but embodiments of the present disclosure are not limited thereto. For example, operation S15 may be performed before, during, or after, providing the capacitor 46 on the surface (e.g., top surface) of the carrier 200 (operation S35, refer to FIG. 11D).

According to embodiments of the present disclosure, semiconductor devices and methods of manufacturing thereof may be provided that enable a large number of chiplets to be included in the semiconductor devices while reducing energy waste and avoiding performance degradation.

According to embodiments of the present disclosure, semiconductor devices and methods of manufacturing thereof may be provided that enable a length of a PDN to be reduced.

According to embodiments of the present disclosure, semiconductor devices and methods of manufacturing thereof may be provided that enable a size of VRM inductors to be minimized without performance degradation.

According to embodiments of the present disclosure, components (e.g., inductor and/or capacitor) of VRMs may be integrated directly under or adjacent to chip dies (e.g., SoC dies) such as to decrease power delivery distance, thereby reducing energy waste.

According to embodiments of the present disclosure, a package architecture and a manufacturing method thereof are provided that may allow an integrated VRM inductor (e.g., inductor 44 or electroplated magnetic core inductor 44A) and an integrated VRM capacitor (e.g., capacitor 46) to be included in a semiconductor device (e.g., a semiconductor package) as a part of an integrated voltage regulator (IVR).

According to embodiments of the present disclosure, the integrated VRM inductor may be, for example, a semiconductor material (e.g., Si) magnetic core inductor (e.g., inductor 44) or an electroplated magnetic core inductor 44A, and the integrated VRM capacitor (e.g., capacitor 46) may be an integrated stack capacitor, which may be integrated directly inside the mold material (e.g., 39) of the semiconductor package and are under or adjacent to the chip dies.

According to embodiments of the present disclosure, the manufacturing method may integrate the inductor (e.g., inductor 44 or electroplated magnetic core inductor 44A) into the semiconductor package by leveraging a prior semiconductor package manufacturing process.

While non-limiting example embodiments have been described above in connection with the drawings, it will be apparent to those skilled in the art that modifications and variations could be made without departing from the scope of the present disclosure.

What is claimed is:

1. A semiconductor device comprising:
a semiconductor chip;
a hybrid interposer connected to the semiconductor chip, the hybrid interposer comprising a mold material and an interconnection region comprising a material different from the mold material, wherein the semiconductor chip is on a first surface of the hybrid interposer that faces in a first direction; and
a voltage regulator module electrically connected to the semiconductor chip and configured to supply a voltage to the semiconductor chip, the voltage regulator module comprising an inductor that is within the hybrid interposer.

2. The semiconductor device of claim 1, wherein the voltage regulator module further comprises a capacitor that is within the hybrid interposer.

3. The semiconductor device of claim 1, wherein the voltage regulator module further comprises a voltage regulator integrated circuit (VRIC) that is configured to, in combination with the inductor, supply the voltage,
wherein the VRIC is on the first surface of the hybrid interposer, and electrically connected to the inductor.

4. The semiconductor device of claim 1, wherein the voltage regulator module further comprises a voltage regulator integrated circuit (VRIC) that is configured to, in combination with the inductor, supply the voltage,
wherein the VRIC is on the first surface of the hybrid interposer, and electrically connected to the inductor, and
wherein the inductor is vertically overlapped by the VRIC in the first direction.

5. The semiconductor device of claim 1, wherein the inductor comprises a magnetic material.

6. The semiconductor device of claim 1, further comprising a printed circuit board,
wherein the hybrid interposer is on a first surface of the printed circuit board that faces in the first direction.

7. The semiconductor device of claim 1, further comprising a printed circuit board,
wherein the hybrid interposer is on a first surface of the printed circuit board that faces in the first direction,
wherein the semiconductor device further comprises a substrate, and
wherein the substrate is between the first surface of the printed circuit board and the hybrid interposer.

8. The semiconductor device of claim 1, further comprising a printed circuit board,
wherein the hybrid interposer is on a first surface of the printed circuit board that faces in the first direction,
wherein the semiconductor device further comprises a substrate,
wherein the substrate is between the first surface of the printed circuit board and the hybrid interposer, and
wherein the substrate comprises an organic material.

9. The semiconductor device of claim 1, wherein the material of the interconnection region is a semiconductor material.

10. The semiconductor device of claim 1, wherein the material of the interconnection region is silicon.

11. A semiconductor device comprising:
a printed circuit board;
a hybrid interposer connected to the printed circuit board on a first surface of the printed circuit board that faces in a first direction, the hybrid interposer comprising a mold material and an interconnection region comprising a material different from the mold material;
a semiconductor chip on a first surface of the hybrid interposer that faces in the first direction; and
a voltage regulator module electrically connected to the semiconductor chip and configured to supply a voltage to the semiconductor chip, the voltage regulator module comprising:
a capacitor within the hybrid interposer;
an inductor within the hybrid interposer; and
a voltage regulator integrated circuit (VRIC) that is on the first surface of the hybrid interposer, and electrically connected to the capacitor and the inductor, wherein the VRIC is configured to, in combination with the capacitor and the inductor, supply the voltage.

12. The semiconductor device of claim 11, further comprising a substrate,
wherein the substrate is between the first surface of the printed circuit board and the hybrid interposer.

13. The semiconductor device of claim 11, wherein the material of the interconnection region is a semiconductor material.

14. The semiconductor device of claim 11, wherein at least one from among the capacitor and the inductor is vertically overlapped by the VRIC in the first direction.

15. The semiconductor device of claim 11, wherein side surfaces of the inductor and the capacitor are in contact with the mold material of the hybrid interposer.

16. A method of manufacturing a semiconductor device that includes a semiconductor chip and a voltage regulator module that is electrically connected to the semiconductor chip and configured to supply a voltage to the semiconductor chip, the method comprising:
forming a hybrid interposer on a first surface of a carrier that faces in a first direction, the forming comprising:
forming a first trace on the first surface of the carrier;
providing an inductor of the voltage regulator module on the first surface of the carrier;
providing a mold material on the first surface of the carrier such that the mold material surrounds side surfaces of the inductor; and
forming a second trace on a first surface of the mold material that faces in the first direction; and
providing the semiconductor chip on a first surface of the hybrid interposer that faces in the first direction.

17. The method of claim 16, wherein the providing the inductor comprises forming a magnetic core of the inductor on the first surface of the carrier by a sputtering process.

18. The method of claim 16, wherein the providing the inductor comprises forming a magnetic core of the inductor on the first trace by an electroplating process.

19. The method of claim 16, further comprising:
attaching at least one substrate on a second surface of the hybrid interposer that faces in a second direction, opposite of the first direction.

20. The method of claim 16, further comprising providing a capacitor of the voltage regulator module on the first surface of the carrier,
wherein the providing the mold material comprises providing the mold material on the first surface of the carrier such that the mold material surrounds side surfaces of the capacitor.
